(19) United States
(12) Patent Application Publication
(10) Pub. No.: US 2007/0237887 A1
(43) Pub. Date: Oct. 11, 2007

(54) Varnishing device and method for the application of varnish

(75) Inventors: Udo Klein, Dietzenbach (DE); Volker Weiss, Frankfurt/Main (DE)

Correspondence Address: Friedrich Kueffner, Suite 910, 317 Madison Avenue, New York, NY, 10017, US

(73) Assignee: LacTec Gesellschaft fur moderne Lackiertechnik mbH

(21) Appl. No.: 11/786,393

(22) Filed: Apr. 11, 2007

(30) Foreign Application Priority Data
Apr. 11, 2006 (DE) 10 2006 016 950.6

(51) Int. Cl. B05C 11/00; C23C 16/52

(52) U.S. Cl. 427/8; 118/692; 118/679; 427/427.1

(57) ABSTRACT

A varnishing device and a procedure for the application of varnish with such a varnishing device, wherein the varnishing device has a varnish repository, a dosing pump connected with the varnish repository, a varnish output device which is connected to the dosing pump via a hose line, and a control device which acts on the dosing pump. A volume compensation device is connected to the hose line having a compensation volume which is connected to the interior of the hose line. The compensation volume can be changed through an externally acting pressure.

### BACKGROUND OF THE INVENTION

1. Field of the Invention

The present invention relates to a varnishing device with a varnish repository, a dosing pump connected to the varnish repository, a varnish output device connected to the dosing pump via a hose line, and a control device acting on the dosing pump. Furthermore, the invention relates to a method for the application of varnish which is conveyed by a dosing pump to a varnish output device.

2. Description of the Related Art

In the following, the invention is described by means of an embodiment in which the varnish output device is guided by a robot or another operation device over a workpiece, while the dosing pump is fixedly arranged at a certain distance therefrom. In order for the varnish to go from the dosing pump to the varnish output device, a hose line of certain flexibility is necessary.

For the present description the term “hose line” should be understood as a line that slightly changes its inner volume during pressure impact. In principle, this is true for all hose lines which are made from an elastomer material, even if it is reinforced. A volume change also occurs when parts of the hose line are made of rigid pipes, for example, metal pipes. In some cases a volume change can also occur when sealing materials in an otherwise rigid line are deformed under an occurring pressure. Such a line should also be included in the term “hose line”.

In some varnishing applications it is necessary to quickly change the deployed varnish amount. If, for example, a varnishing robot moves the varnish output device at a given speed and the width of a color stripe applied onto a workpiece is to be doubled, then the amount of varnish per time also has to be doubled. The goal is to avoid that the stripe widens gradually, i.e., ramp-like. Rather, what is desired is a preferably steplike transition from the narrow to the wide part of the stripe.

When using a hose line, i.e., a line whose volume changes with changes in pressure, it is almost impossible to change the amount of varnish deployed to the varnish output device fast enough in the appropriate manner through a change in the conveyance-mass. At the movement speeds of a robot which can be in the range of 1 m/s this leads to relatively large transition areas between the application area with low varnish output and an output area with higher varnish output. These transition areas are often no longer accepted. Also, a procedure in which the dosing pump is started with a greater varnish amount before reaching the varnish output area is not acceptable because this only moves the transition area but it does not reduce its size.

### SUMMARY OF THE INVENTION

It is the object of the present invention to be able to change the amount of varnish to be dispensed more quickly.

In a varnishing device of the kind initially described, this object is met by connecting a volume compensation device with the hose line which has a compensation volume connected with the inside of the hose line, wherein the compensation volume is changeable through an externally acting pressure.

In order to facilitate the subsequent explanation, the explanation of the invention will be provided in the case of an increase of the dispensed varnish mass. During a reduction of the dispensed varnish mass the illustrations can then be applied analogously.

If one wants to increase the varnish mass to be dispensed at the varnish output device, the dosing pump has to convey an appropriately larger varnish volume. Since a dosing pump generally has a relatively fast operating drive, for example, a servo drive, the changed output mass at the exit of the dosing pump is available relatively quickly, i.e., within a few hundredths of a second. The varnish mass conveyed by the dosing pump also arrives in the hose line leading to the varnish output device. However, this raises the pressure in the hose line, because the varnish output device in the simplest case offers a constant flow resistance and the flow speed increases. The pressure increase, in turn, causes a volume increase in the hose so that the varnish amount conveyed by the dosing pump initially has to be used to replenish this rise in volume. This is a reason why the varnish mass dispensed at the varnish output device does not rise at the same speed as the varnish mass conveyed at the output of the dosing pump. With the volume compensation device it can now be achieved that an additional varnish mass is deployed into the hose line so that the desired increased varnish mass is now available at the varnish output device earlier than previously possible. However, no definite volume is dispensed into the hose line; rather the deployment is effected in a pressure controlled manner. At an increase in pressure onto the or in the volume compensation unit, the compensation volume is decreased and the varnish mass located therein is pressed into the hose line. In this manner, the hose line can be amplified much faster to the volume generated by the new conveyance mass without interfering with the conveying characteristics of the dosing pump which delivers a constant mass independent of the existing pressure. After the “pressure surge”, the pressure inside the hose line then adjusts very quickly to a value that meets the desired varnish output volume.

Preferably, the compensation volume is at least as big as a volume change of the hose line between a minimum pressure and a predetermined maximum pressure. Thus, through the compensation volume, a complete compensation of the volume increase of the hose line can be achieved. Conversely, in the case of a decrease of the conveyance mass and the thereby caused pressure reduction on the inside of the hose, which again causes a reduction in the volume of the hose line, it can of course be achieved that the varnish mass displaced form the hose line through contraction can be incorporated in the compensation volume.

Preferably, the volume compensation device has a pressure input connected to a pressure fluid repository, wherein the pressure fluid repository has an output pressure adjustable by way of a controlling device. The controlling device is thus capable of adjusting the pressure of the pressure fluid repository which is used for changing the compensation volume in such a way that for every case of use the desired volume compensation can be achieved on the inside of the hose line.

In accordance with a particularly preferred embodiment, the pressure fluid repository has a proportional valve. With a proportional valve it is an easy task to adjust to a particular pressure.

Preferably, the compensation volume is delimited by a diaphragm. The use of a diaphragm is a relatively easy task in order to devise a variable compensation volume. Sealants between movable parts are not necessary. The diaphragm which generally is of certain flexibility can rather be deformed into the compensation volume in order to decrease the compensation volume. Since the side opposite the compensation volume is exposed to the pressure from the pressure fluid repository, for example, a compressed air repository, this pressure can act over a relatively large plane, in order to change the compensation volume.

Preferably, the compensation volume is arranged in series. This is of great advantage when changing varnish. In case of a color change all the parts, that have previously come into contact with a different color, have to be cleaned, thus also the hose line and the compensation volume. If the compensation volume is arranged in series with the hose line, then a cleaning fluid passing through the hose line invariably also has to pass through the compensation volume. This is a simple measure in order to ensure that the cleaning fluid can also wash away the varnish residues present in the compensation volume.

Preferably, the compensation volume is arranged closer to the dosing pump than to the varnish output device. The pressure surge produced to displace the varnish from the compensation volume thus cannot escape through the varnish output device without effect, but rather it increases the volume of the hose line.

This is particularly true when the compensation volume is arranged at the end of the hose line to which the dosing pump is connected. Since the dosing pump generally does not have any parts that show an increase of volume during a pressure increase, the entire pressure increase is passed onto the inside of the hose line. Moreover, this embodiment has the advantage that the hose line is scraped over its entire length, i.e., it is traversed by a so-called scraper. Thus it is possible to press nearly all the varnish residues present in the hose line during a color change almost completely back into the varnish repository without having to bypass the volume compensation device with the scraper.

It is also advantageous when the controlling equipment has a repository device in which a connection is recorded between a varnish mass per time conveyed from the dosing pump and a then prevailing pressure in the hose line. Such a recordation device can be formed, for example, as a look-up table. If, as mentioned above, the varnish output device shows a constant flow resistance, because it has, for example, an output nozzle with a constant cross-section, then a change in the conveyance mass of the dosing pump results in a change of the inside pressure. An increase in the conveying mass thus produces an increase in pressure. Knowing this connection, the pressure surge with which the varnish is squeezed out of the compensation volume can then be adjusted to the new conveying mass so that, within a short period of time, inside the hose line the pressure prevails that is necessary for the new conveying mass.

Preferably, the control device changes the pressure and the conveying mass of the dosing pump in a predetermined timely interrelationship. In particular, the control device can change the pressure and the conveying mass simultaneously, or it can modify the pressure immediately before the change in the conveying mass. In the final result it is thus ensured that in case of an increase in the conveying mass almost simultaneously a corresponding modified output mass at the varnish output device is available.

The object in the procedure for a method of the initially mentioned type, the object of the invention is met by feeding, during a change in the conveying mass of the dosing pump, a varnish volume into the hose line or discharged from the hose line which is put under a compensation pressure allocated to the conveying mass.

As described above in connection with the varnishing device, it is possible in this way to counterbalance the volume change resulting from the pressure change inside the hose line from the volume compensation unit so that with the help of the fed-in or discharged varnish volume the volume change in the hose line can be counterbalanced and the varnish volume conveyed by the dosing pump can be dispensed practically simultaneously at the varnish output device. In this manner, it is possible to obtain relatively poignant transitions between two areas that should be varnished with different varnish volumes.

According to a preferred feature the compensation pressure at the input is higher and at the output is lower than the operating pressure in the hose line corresponding to the conveyance. Thereby, the volume change of the hose line in case of a pressure change is overcompensated or undercompensated. In fact, this produces a small overswing or a small prepulse at the dispensed varnish mass. However, offhand this exceeding or undercutting is acceptable because it leads to an even sharper delimitation between areas of different varnish mass.

Preferably, the conveying mass and the pressure are changed simultaneously. Thus, practically immediately after the change of the conveying mass of the dosing pump the conveyed varnish mass is available at the varnish output device.

The various features of novelty which characterize the invention are pointed out with particularity in the claims annexed to and forming a part of the disclosure. For a better understanding of the invention, its operating advantages, specific objects attained by its use, reference should be had to the drawing and descriptive matter in which there are illustrated and described preferred embodiments of the invention.

### BRIEF DESCRIPTION OF THE DRAWING

In the drawing:

FIG. 1 is a schematic illustration of a varnishing device, and

FIG. 2 is a schematic illustration of a volume compensation device.

### DETAILED DESCRIPTION OF THE INVENTION

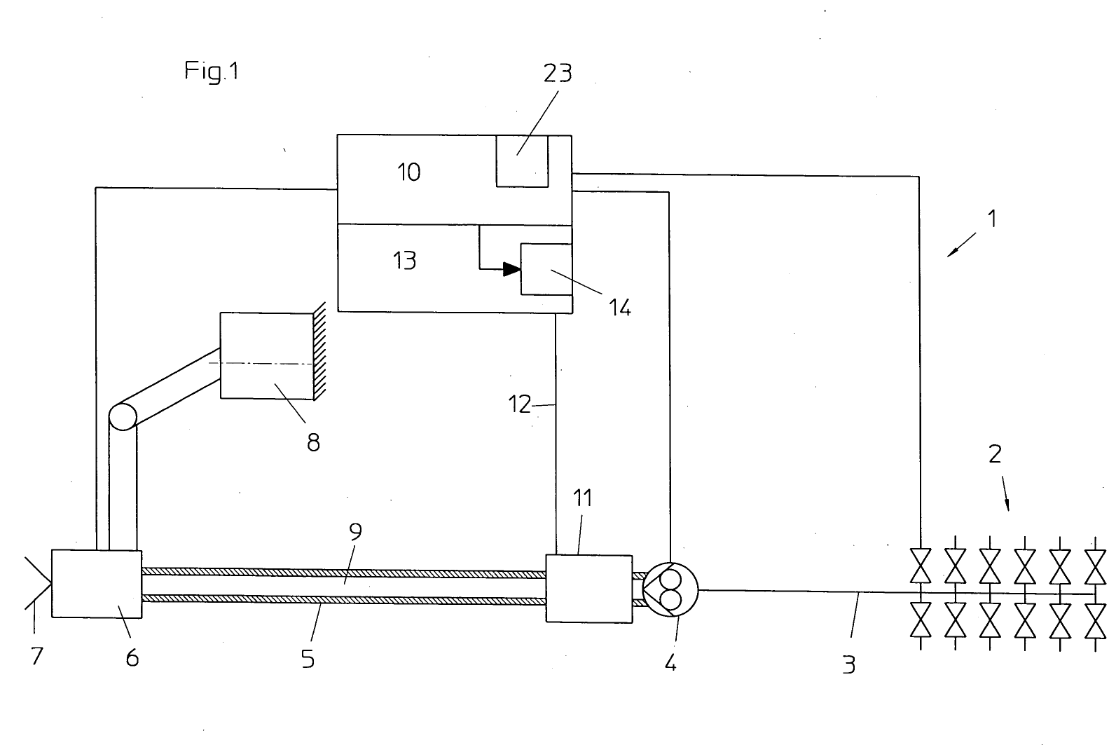

FIG. 1 shows a schematic embodiment of a varnishing device 1 with a varnish repository 2 which is designed as a varnish changer. The varnish repository 2 is connected via a line 3 to a dosing pump 4. The dosing pump is a volumetric pump, i.e., it conveys relatively independent from the pressures present in the varnishing device 1 a given mass of varnishing liquid per time. The delivery volume of the dosing pump is adjustable.

The dosing pump 4 is connected via a hose line 5 to a varnish output device 6 which dispenses the conveyed varnish through a valve 7. The varnish output device 6 is handled by an only schematically depicted robot 8. The robot 8 can guide the valve 7 along a predetermined movement path in order to cover, for example, certain components with a varnish layer. Accordingly, the hose line 5 has to have certain flexibility. In order to ensure this flexibility, the hose line 5 is normally made of an elastomer material. The hose line 5 of an elastomer material, however, changes the volume of its interior 9 according to the pressures present in the interior. If the pressure rises, the volume of the interior 9 increases slightly. If the pressure in the interior 9 diminishes, the volume of the interior 9 decreases accordingly up to a minimal value.

A control device 10 is provided which controls the varnish repository 2 as well as the dosing pump 4. The control device 10 is also connected to the varnish output device 6 in order to, for example, close a there present valve when a varnish output should be terminated.

The control device 10 is also connected to the robot 8 so that the control device 10 is always informed about the position of the varnish output device 6 and the valve 7.

When the control device 10, because of a preset varnishing program, knows that in a predetermined movement segment of the varnish output device 6 a higher varnish mass has to be applied, for example, because a spray beam of the varnish with a greater width should be produced, while the applied layer thickness remains the same, the dosing pump 4 is adjusted to an appropriately higher delivery rate. The dosing pump 4 reacts very fast so that theoretically immediately after the change of the delivery rate of the dosing pump 4 the then required varnish mass should be available at the varnish output device 6.

Due to the extensibility of the hose line 5 this is not the case. If, for example, the dosing pump 4 delivers a greater conveyance mass, the pressure in the interior 9 of the hose line 5 initially rises, because the flow resistance which the varnish output device sets against the varnish does not change. The pressure increase, in turn, causes a slight volume increase in the hose line 5, so that the additional mass of the varnish conveyed by the dosing pump 4 has to be used first in order to fill up this volume increase.

This time lag brings forth that the increased varnish mass is not immediately available at the varnish output device 6, but rather only a short while later. Even if this short while is only the fraction of a second, for example, a fourth of a second, through this delay a relatively large transition area is produced, if one considers that the robot 8 moves the varnish output device 6 at a speed in the magnitude of 1 m/s. At a delay of a fourth of a second one ends up with a transition area of 25 cm in length, in which the deployed varnish amount is increased. A transition area of this size is in many tasks, particularly in the lacquering of motor vehicle parts, no longer acceptable. Incidentally, the length of the transition area increases according to the length of the hose line 5. Since in the varnishing of big parts, for example, truck bodies or bus bodies, one needs by all means hose lines with a length in the magnitude of 15 to 20 m, the length of the transition area would become too large.

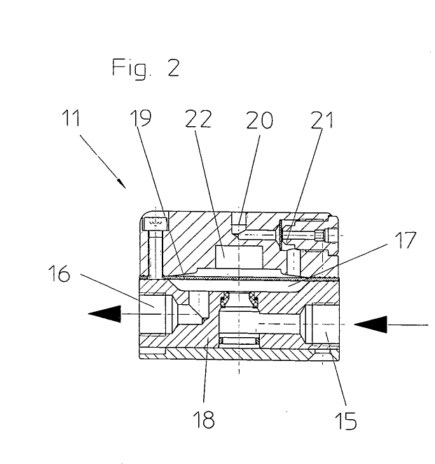

In order to facilitate a faster change of the varnish mass deployed through the varnish output device 6, a volume compensation device 11 is arranged at the end of the hose line 5 where the dosing pump 4 is mounted, and whose configuration is illustrated in more detail in FIG. 2.

The volume compensation device 11 is connected via a line 12 with a pressure fluid repository 13. The pressure fluid repository 13 is preferably a compressed air repository. The pressure reaching the volume compensation device 11 from the compressed air repository 13 is adjusted via a proportional valve 14 which is controlled by the control device 10.

The volume compensation device 11 has an input 15 which is connected to the dosing device 4, and an output 16 which is connected to the interior 9 of the hose line 5. Between the input 15 and the output 16 a compensation volume 17 is arranged which is delimitated, on the one hand, by a housing part 18 and, on the other hand, by a diaphragm 19. The diaphragm 19 is elastically deformable. When it is moved toward the housing part 18, the compensation volume 17 decreases. When it is moved away from the housing part 18, the compensation volume 17 increases.

A pressure port 20 is connected with the line 12. It empties through an only schematically illustrated valve 21 which is normally open into a pressure chamber 22 arranged on the side of the diaphragm 19 facing away from the compensation volume 17. The diaphragm 19 is moved in the direction of the compensation volume 17 and diminishes the compensation volume 17, when the pressure in the pressure chamber 22 is greater than the pressure in the compensation volume 17 and thus in the interior 9 of the hose line 5.

Thus, the compensation volume 17 is arranged in series with the interior 9 of the hose line 5. This is advantageous for cleaning. In case of a change of color the hose line 5 can be scraped, i.e., one can push a scraper from the varnish output device 6 to the volume compensation device 11 and transport the varnish residues present in the hose line 5 back to the varnish repository. In this manner, in a subsequent rising procedure not only the interior 9 of the hose line 5 but also the interior of the volume compensation device 11 gets flushed.

The control device 10 now does not only actuate the dosing pump 4 but also the volume compensation device 11.

When, for example, the dispensary volume of the varnish through the varnish output device 6 should be augmented, the output of the dosing pump 4 is increased. Simultaneously, through the proportional valve 14 a pressure is produced in the pressure chamber 22 that corresponds to the pressure which pertains to the then preset output or it rises slightly above it. Through this pressure, varnish fluid is eliminated from the compensation volume. The compensation volume is at least as great as the volume difference of the hose line 5 between a minimum pressure and a maximum pressure. Thus, the varnish volume from the compensation volume 17 is definitely sufficient to compensate for the volume increase of the interior 9 in the hose line 5. Since no varnish is used for this compensation that would need to be conveyed first by the dosing pump, but rather varnish that is already present in the compensation volume 17, the required varnish volume is practically available at the varnish output device 6 with the start of the dosing pump 4.

If the varnish volume to be dispensed should be decreased, the dosing pump 4 is shut down. Simultaneously, the control device 10, through the proportional valve 4, sets a pressure in the pressure chamber 22 which corresponds to the then valid output or lies slightly below. The hose line 5 contracts somewhat because of the reduced pressure. The thereby displaced varnish fluid is received in the compensation volume 17, wherein the diaphragm 19 moves away from the housing part 18 and thereby increases the compensation volume.

Since the diaphragm 18 is controlled through pressure, steady state conditions are quickly recovered in the hose line 5. Within a very short time after the change of pressure in the pressure chamber 22 a pressure is reached in the interior 9 which corresponds to an output volume dispensed through the dosing pump 4.

The control device 10 has a storage device 23 which is organized, for example, in the form of a “look-up” table. For every conveyance mass that can be preset in the dosing pump 4 there is a pressure value stored which then develops in the interior 9 of the hose line 5. The control device can now in the case of increase set a slightly higher pressure or, in the case of decrease of the output set a slightly lower pressure in the pressure chamber 22.

While specific embodiments of the invention have been shown and described in detail to illustrate the inventive principles, it will be understood that the invention may be embodied otherwise without departing from such principles.

We claim:

1. A varnishing device comprising a varnish repository, a dosing pump connected to the varnish repository, a varnish output device connected to the dosing pump via a hose line, and a control device for controlling the dosing pump, further comprising a volume compensation device connected to the hose line the volume compensation device having a compensation volume connected to the interior of the hose line wherein the compensation volume is changeable through an externally acting pressure.

2. The varnishing device according to claim 1, wherein the compensation volume is at least of the same magnitude as the volume change of the hose line between a minimum pressure and a preset maximum pressure.

3. The varnishing device according to claim 1, wherein the volume compensation device has a pressure input connected to a pressure fluid repository, wherein the pressure fluid repository has an output pressure adjustable by means of the control device.

4. The varnishing device according to claim 3, wherein the pressure fluid repository has a proportional valve.

5. The varnishing device according to claim 1, wherein the compensation volume is delimited by a diaphragm.

6. The varnishing device according to claim 1, wherein the compensation volume is arranged in series with the interior of the hose line.

7. The varnishing device according to claim 1, wherein the compensation volume is arranged closer to the dosing pump than to the varnish output device.

8. The varnishing device according to claim 7, wherein the compensation volume is arranged at the end of the hose line on which the dosing pump is mounted.

9. The varnishing device according to claim 1, wherein the control device has a storage device on which is stored a relationship between a varnish volume dispensed from the dosing pump per unit or time and a then prevailing pressure in the hose line.

10. The varnishing device according to claim 1, wherein the control device alters the pressure and the conveyance mass of the dosing pump in accordance with a preset time relation.

11. A method for the application of varnish which is conveyed by a dosing pump through a hose line to a varnish output device, the method comprising, at a change of the conveyance mass of the dosing pump, feeding a varnish volume into the hose line or discharging varnish volume from the hose line, and placing the varnish volume under a compensation pressure assigned to the conveyance mass.

12. The method according to claim 11, wherein the compensation pressure during feeding is higher and during at the discharge is lower than an operating pressure corresponding to the conveyance in the hose line.

13. The method according to claim 11, comprising simultaneously changing the conveyance mass and the pressure changed.
